(19) United States
(12) Patent Application Publication
(10) Pub. No.: US 2026/0058231 A1
(43) Pub. Date: Feb. 26, 2026

(54) BATTERY SWELL DETECTION AND ADAPTIVE ANTENNA TUNING

(71) Applicant: Meta Platforms Technologies, LLC, Menlo Park, CA (US)

(72) Inventors: Jason Michael Battle, Bothell, WA (US); Sung Hoon Oh, San Jose, CA (US)

(21) Appl. No.: 19/305,981

(22) Filed: Aug. 21, 2025

Related U.S. Application Data
(60) Provisional application No. 63/686,428, filed on Aug. 23, 2024.

(51) Int. Cl. H01M 10/48; G01R 21/133; H01M 10/44; H01Q 23/00; H02J 7/00

(52) U.S. Cl. CPC H01M 10/48; H01M 10/44; H01Q 23/00; H02J 7/007188; G01R 21/1331

(57) ABSTRACT

A system comprising a battery, an antenna, a radio frequency coupler, operably placed in a transmit path of the antenna, that is configured to generate an output signal detailing an amount of power reflected back to a radio frequency power amplifier, a radio frequency signal conditioning circuitry that is configured to receive the output signal from the radio frequency coupler and convert the output signal for processing by an analog to digital converter, and a microprocessor that is configured to adjust a charging voltage for the battery based on whether a change in a thickness displacement of the battery, calculated from the output signal, exceeds a swelling response threshold.

### CROSS-REFERENCE TO RELATED APPLICATIONS

The present disclosure is related and claims priority under 35 U.S.C. § 119(e) to U.S. Prov. Appln. No. 63/686,428, entitled SYSTEMS AND METHODS FOR IN-SITU BATTERY SWELL DETECTION AND ADAPTIVE ANTENNA TUNING to Jason Michael Battle and Sung Hoon Oh, filed on Aug. 23, 2024, the contents of which are hereby incorporated by reference in their entirety, for all purposes.

### TECHNICAL FIELD

The present disclosure is generally to battery management systems and wireless communication systems. More specifically, the present disclosure is related to techniques for monitoring battery conditions and tuning antenna performance in electronic devices, particularly those incorporating lithium-ion batteries and radio frequency (RF) communication components.

### BACKGROUND

Consumer electronic devices increasingly rely on lithium-ion battery technology due to their high energy density and rechargeability. However, these batteries degrade over time, particularly under elevated operating temperatures, which can lead to the generation of byproduct gases and subsequent swelling of the battery cell. Traditional approaches to monitor or predict battery swelling include preemptive modeling techniques, which require extensive calibration and validation across different battery types, and reactive methods such as contact-based sensors. While modeling can be costly and time-consuming, contact-based sensors often consume valuable internal space and may reduce overall energy density. Additionally, antenna systems within electronic devices are sensitive to changes in their surrounding environment, including mechanical shifts caused by battery swelling, which can affect impedance and signal performance.

### SUMMARY

The subject disclosure provides for systems and methods for in-situ battery swell detection and adaptive charging control. One aspect of the present disclosure relates to a method for managing battery swelling in a device. The method includes sampling transmit antenna power via a radio frequency coupler placed in a transmit path of an antenna, receiving an output signal from the radio frequency coupler and converting the output signal via signal conditioning circuitry and an analog to digital converter, calculating a thickness displacement of a battery based on the output signal, determining whether the thickness displacement exceeds one or more swelling response thresholds, and adjusting a charging voltage of the battery based on the determination.

Another aspect of the present disclosure relates to a system configured for battery swell detection and voltage adjustment. The system includes a battery, an antenna, a radio frequency coupler operably placed in a transmit path of the antenna and configured to generate an output signal detailing an amount of power reflected back to a radio frequency power amplifier, radio frequency signal conditioning circuitry configured to receive and convert the output signal for processing by an analog to digital converter, and a microprocessor configured to adjust a charging voltage for the battery based on whether a change in a thickness displacement of the battery, calculated from the output signal, exceeds a swelling response threshold.

Yet another aspect of the present disclosure relates to a non-transitory computer-readable storage medium comprising instructions stored thereon, which when executed by one or more processors, cause the one or more processors to perform operations comprising: sampling transmit antenna power via a radio frequency coupler placed in a transmit path of an antenna, receiving an output signal from the radio frequency coupler and converting the output signal via signal conditioning circuitry and an analog to digital converter, calculating a thickness displacement of a battery based on the output signal, determining whether the thickness displacement exceeds one or more swelling response thresholds, and adjusting a charging voltage of the battery based on the determination.

These and other embodiments will be evident from the present disclosure.

### BRIEF DESCRIPTION OF THE DRAWINGS

The present technology is illustrated by way of example, and not by way of limitation, in the figures of the accompanying drawings, in which like reference numerals refer to similar elements including:

FIG. 1 illustrates a network architecture used for implementing a swell detection and adaptive antenna tuning system, in accordance with one or more embodiments.

FIG. 2 is an illustration of an exemplary block diagram for in-situ battery swell detection and adaptive antenna tuning, according to certain embodiments.

FIG. 3 is an illustration of exemplary flowcharts for in-situ battery swell detection and adaptive antenna tuning, according to some embodiments.

FIG. 4 is an illustration of exemplary flowcharts for in-situ battery swell detection and adaptive antenna tuning, according to some embodiments.

FIG. 5 is an illustration of exemplary augmented-reality glasses that may be used in connection with embodiments of this disclosure.

FIG. 6 is an illustration of an exemplary virtual-reality headset that may be used in connection with embodiments of this disclosure.

FIG. 7 is a block diagram illustrating a computer system used to at least partially carry out one or more of operations in methods disclosed herein, according to some embodiments.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

In the following detailed description, numerous specific details are set forth to provide a full understanding of the present disclosure. It will be apparent, however, to one ordinarily skilled in the art, that the embodiments of the present disclosure may be practiced without some of these specific details. In other instances, well-known structures and techniques have not been shown in detail so as not to obscure the disclosure.

### General Overview

One of the most challenging aspects of employing lithium-ion battery technology in consumer devices is the battery's sensitivity to higher operating temperatures, which may accelerate degradation processes. For example, these degradation processes may generate byproduct gases that accumulate within the hermetically sealed battery cell, causing the battery cell's soft pouch to swell. Given the limited space between the battery enclosure and the system's other internal components, it becomes increasingly important to prevent the degradation processes as the battery enclosure may become mechanically compromised. While preemptive methods to predict swelling of the battery may be employed through modeling, the time to build, tune, and verify each model of the battery may become expensive across a large population of batteries. Comparatively, reactive approaches (for example, generally contact-based sensors) may be space intensive due to the amount of volume an extra design component consumes, lessening energy density.

The present disclosure is directed to systems and methods for in-situ battery swell detection and adaptive antenna tuning using a radio frequency (RF) coupler to monitor antenna performance. As a battery enclosure swells, an internal air gap between the battery cell and other internal components in the system may be decreased, causing a change in antenna impedance and consequently a higher amount of reflected power back to an RF power amplifier. A mathematical relationship between the reflected power and the battery swelling level may be established such that the system derives an approximate positional increase in the thickness displacement of the battery. In this manner, as the microprocessor receives a readable output signal from the RF coupler, indicating a change in thickness displacement, the system can then take actions based on the battery thickness displacement. In some embodiments, system actions may include reducing the charging voltage in response to detected swelling, compensating for antenna output power via a tunable impedance network, or similar adjustments. For instance, by dynamically managing charging conditions, the rate of future swelling may be mitigated over time, resulting in reduced overall battery expansion across its lifecycle.

Embodiments, as disclosed herein, provide a solution using battery swell detection and adaptive antenna tuning by leveraging a radio frequency (RF) coupler to monitor changes in antenna impedance caused by battery swelling. This enables real-time adjustment of battery charging voltage and antenna impedance matching, reducing battery degradation and preserving wireless performance without the need for contact-based sensors or pre-built models. Implementing a non-contact, wireless sensing approach can preserve battery volume, reduce cost, and simplify design across different programs/applications. This approach enables non-contact, in-situ monitoring of battery health and supports responsive system actions, such as antenna impedance matching, without the need for physical sensors or additional space-consuming components.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (for example, real-world) content. The artificial-reality content may include video, audio, haptic feedback, or some combination thereof, any of which may be presented in a single channel or in multiple channels (such as stereo video that produces a three-dimensional (3D) effect to the viewer).

Additionally, in some embodiments, artificial reality may also be associated with applications, products, accessories, services, or some combination thereof, that are used to, for example, create content in an artificial reality and/or are otherwise used in (e.g., to perform activities in) an artificial reality.

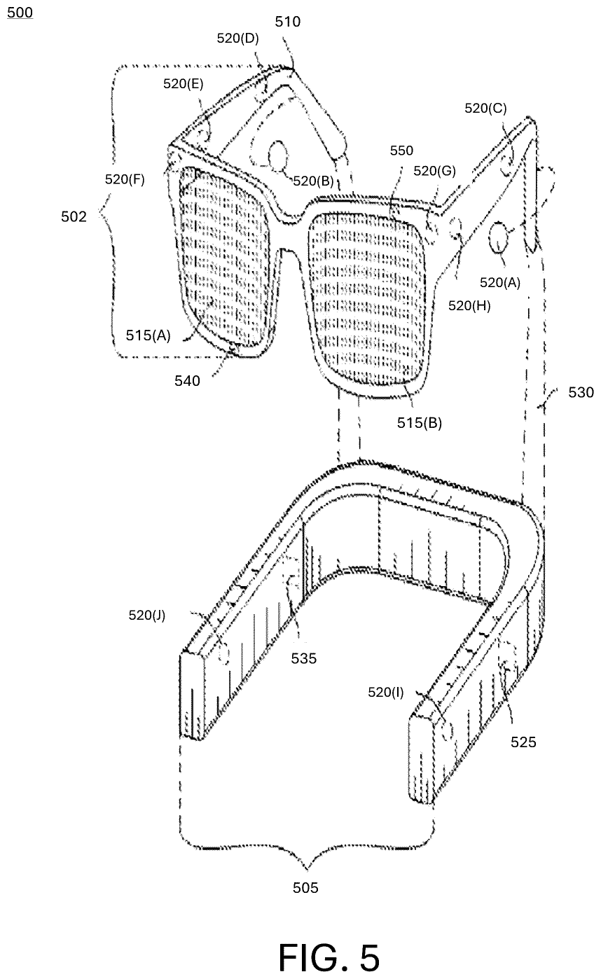

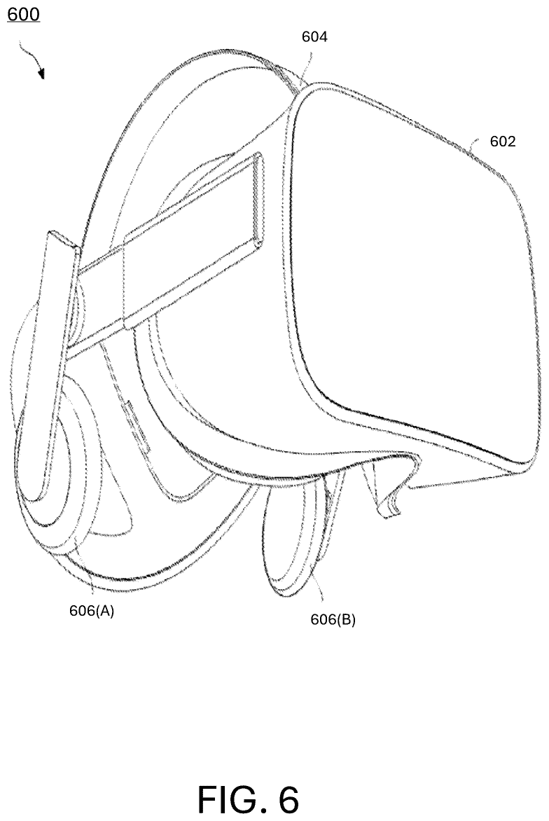

Artificial-reality systems may be implemented in a variety of different form factors and configurations. Some artificial-reality systems may be designed to work without near-eye displays (NEDs). Other artificial-reality systems may include an NED that also provides visibility into the real world (for example, augmented-reality system 500 in FIG. 5) or that visually immerses a user in an artificial reality (for example, virtual-reality system 600 in FIG. 6). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

### Example Architecture

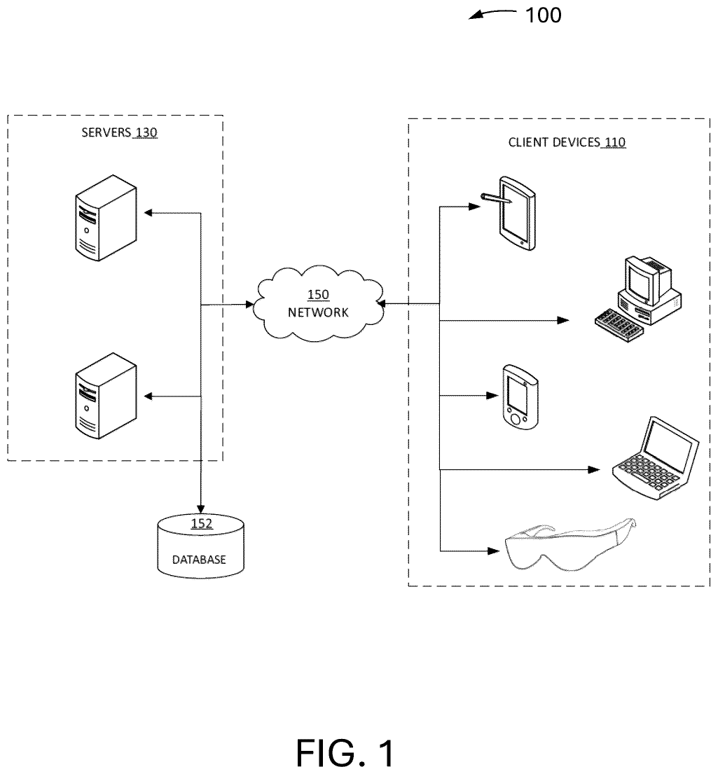

FIG. 1 illustrates a network architecture 100 for a battery swell detection and management system, according to some embodiments. Architecture 100 can include server(s) 130 and database(s) 152, communicatively coupled with one or more client devices 110 via a network 150. Any one of servers 130 can host an application configured to monitor battery health, analyze sensor data, and manage system-level responses. Servers 130 may be implemented as cloud-based platforms, non-cloud-based systems, or hybrid configurations depending on deployment requirements.

Client devices 110 can include any of a laptop computer, desktop computer, mobile device, or embedded system within a host device (e.g., wearable, AR/VR headset, or consumer electronics). These devices may serve as user interfaces or local processing nodes for accessing battery health data, system diagnostics, and operational controls. In various implementations, client devices 110 can communicate over wired or wireless channels to share data, distribute processing, or coordinate with peripheral sensors. Client devices may also be configured to receive and process data signals from battery-integrated components such as RF couplers, analog-to-digital converters, and microcontrollers.

Servers 130 can host a battery management platform configured to analyze data from a plurality of sources, including environmental conditions, device usage patterns, and battery-specific sensor outputs. Based on this data, the platform can generate system-level recommendations, adjust charging parameters, and initiate impedance tuning operations. For example, data transmitted via network 150 from client device 110 may be received by server 130, where it is processed and stored in conjunction with database 152 to support adaptive battery control and performance optimization.

Database(s) 152 can store application-related data, including trained models for battery swelling prediction, historical sensor readings, charging profiles, and contextual metadata. These databases may be centralized or distributed across multiple computing nodes, either co-located with servers or geographically dispersed. Stored data may include battery type identifiers, swelling response thresholds, impedance tuning parameters, and operational history, supporting long-term reliability and system adaptability.

Network 150 can include any one or more of a local area network (LAN), wide area network (WAN), the Internet, mesh network, hybrid network, or other wired or wireless communication infrastructure. Network 150 may support various topologies, including bus, star, ring, mesh, tree, or hierarchical configurations. Client devices may connect to network 150 via wired or wireless interfaces, enabling real-time or near real-time data exchange between system components.

### Battery Swell Detection and Management System

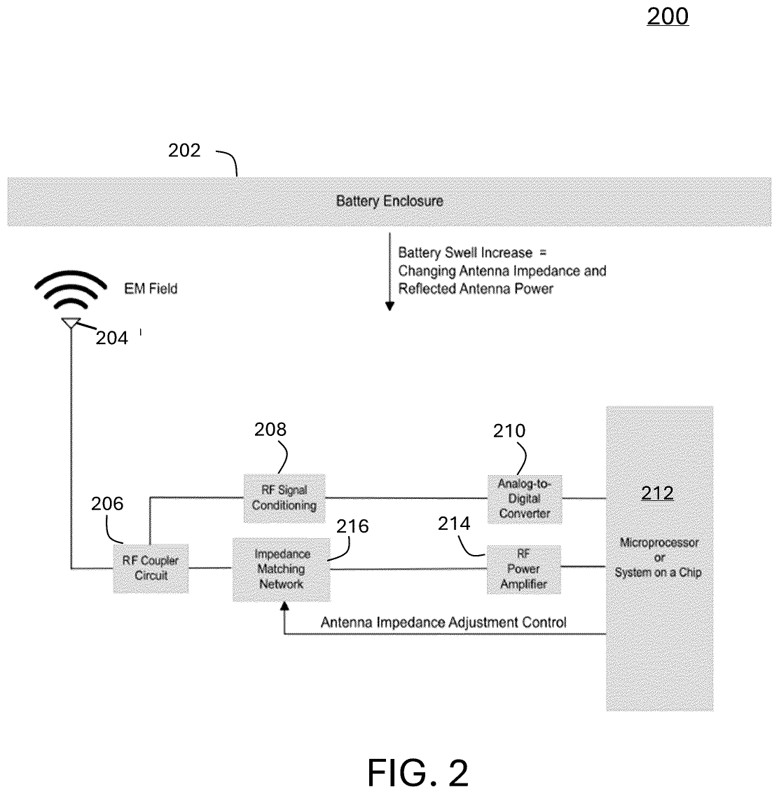

FIG. 2 illustrates a block diagram for detecting the swell of a battery 202. System 200 may include an RF coupler 206 that is configured to generate and send an output signal via an analog to digital converter (ADC) 210 to a microprocessor (MCU) 212. RF coupler 206 may be placed in a transmit path of an antenna 204 to sample the amount of reflected power back to an RF power amplifier 214 and understand the performance of antenna 204. For example, the output signal may be received by RF signal conditioning circuitry 208 (e.g., RF envelope detector), which converts the output signal for digital processing by ADC 210. Consequently, ADC 210 may then convert the output signal into a readable format for MCU 212. In some embodiments, components such as the ADC may be internal to the MCU and leveraged as existing peripherals, while others like the signal conditioning circuitry and coupler may require external integration, incurring additional cost and space.

In some embodiments, if the converted output signal indicates a higher amount of reflected power back to the RF power amplifier 214, MCU 212 may detect a positional increase in a thickness displacement of battery 202. For example, as the swell of battery 202 increases, an internal air gap between battery 202 and other internal components (e.g., antenna 204, signal conditioning circuitry 208, MCU 212) may decrease, altering the impedance of antenna 204 and resulting in increased reflected power. This impedance change is particularly relevant in antenna architectures where the air gap is critical to performance, such as in metal-enclosed wearable devices like smartwatches. An established mathematical relationship between the reflected power and the battery swelling level may allow MCU 212 to derive the approximate positional increase in the thickness displacement of battery 202.

In some implementations, this relationship may represent a displacement of the thickness of battery 202 from its origin, rather than an absolute positional increase, which may vary due to inherent manufacturing differences in initial battery thickness. In this manner, a swelling response threshold may be established, and the maximum charging voltage of battery 202 may be adjusted accordingly based on the received output signals.

In some embodiments, a series of thresholds may be established with progressively decreasing charging voltage levels, enabling more gradual system adjustments. Additionally, an impedance matching network 216 (i.e., antenna tuner) may be dynamically adjusted to reoptimize the impedance of antenna 204 based on the detected change in battery thickness displacement. This adjustment may be performed via a control line from MCU 212 to the impedance network, allowing the system to compensate for antenna performance degradation due to gap shrinkage and maintain optimal wireless transmission. This dual-function approach enables both early intervention in battery charging and dynamic antenna performance tuning in response to physical changes within the device.

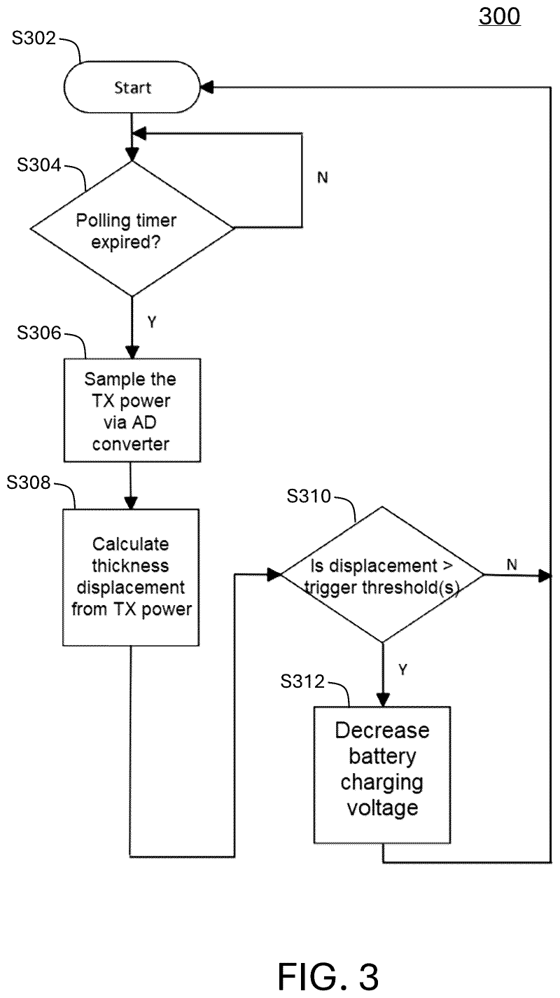

FIG. 3 illustrates a partial implementation flowchart 300 for in-situ battery swell detection and adaptive antenna tuning, according to one or more embodiments. The partial implementation flowchart 300 illustrates a series of steps for detecting battery swelling, where a battery charging voltage is decreased due to a thickness displacement of a battery.

The process begins at S302 (start node) and proceeds to S304 where the step includes checking whether a polling timer has expired. If not, the polling continues. Once the timer expires, the process proceeds to S306. The system may continuously monitor antenna impedance to enable early intervention before physical contact or maximum swelling occurs.

At S306, process 300 includes sampling the transmit (TX) antenna power via an analog-to-digital (AD) converter. According to embodiments, an RF coupler may sample the amount of reflected power in the form of an output signal and send the output signal to an analog-to-digital converter for digital processing.

According to embodiments, the presence of the RF coupler removes the need for contact-based battery swelling sensors, saving the system valuable cost and space. Furthermore, because the system may not rely on a conductive material or a sensor to work, there is no confinement on specific materials for a battery's enclosure.

At S308, process 300 includes calculating thickness displacement from the TX antenna power sample. The calculation can be based on a transfer function used to derive the thickness of the battery using the TX power. Based on a thickness of the battery, an amount of displacement can be defined. Using this approach, there may be no need to rely on a static, offline-generated model to determine a battery's swelling level, but rather a relative change in thickness that is derived in-situ. In some embodiments, the process 300 may include determining battery swelling based on a relative change in thickness from an initial baseline rather than an absolute thickness value.

At S310, process 300 includes determining whether the displacement meets or exceeds one or more trigger thresholds. These thresholds may be configured as a single limit or a series of progressively increasing thresholds, depending on the characteristics of the battery and its swelling behavior. As such, a thickness displacement detailing the approximate positional increase of the battery is calculated and evaluated to determine if a swelling response threshold is triggered. If the trigger thresholds are met or exceeded, the process proceeds to S312. If they are not met, the process 300 returns to the start at S302.

At S312, process 300 includes decreasing battery charging voltage based on the displacement meeting or exceeding the trigger thresholds. If a threshold is exceeded, the battery charging voltage may be decreased by a scheduled amount. This voltage derating may occur once or iteratively, in an adaptive fashion, based on the severity and progression of the swelling. The specific derating schedule may be determined through empirical characterization, as battery swelling behavior can vary across different battery types and programs. By non-limiting example, one implementation may use three thresholds with 25 millivolt decrements, while another may apply a single 100 millivolt reduction. The choice of schedule balances runtime impact with long-term battery reliability and may be tuned to minimize perceptible loss in device performance.

According to embodiments, if the swelling response threshold is not triggered, partial implementation flowchart 300 restarts.

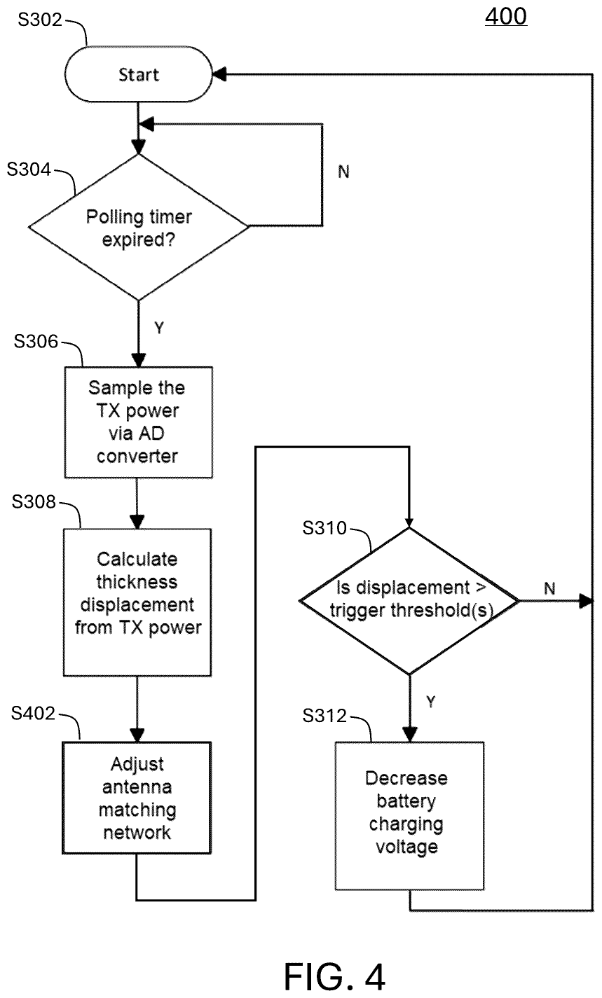

FIG. 4 illustrates a full implementation flowchart 400 for in-situ battery swell detection and adaptive antenna tuning, according to one or more embodiments. The full implementation flowchart 400 includes adaptive antenna tuning. Similarly to partial implementation flowchart 300, steps S302-S308 may be identical in full implementation flowchart 400, and therefore the descriptions are omitted here.

According to the full implementation flowchart 400, after calculating thickness displacement from the TX power, the process 400 proceeds to S402. At S402, process 400 includes adjusting an antenna matching network, tuning the antenna performance. In this full implementation flowchart 400, an adjustable version of the antenna impedance matching network may allow the system to compensate for the reflected power. In this manner, the antenna and overall wireless connectivity performance may be preserved, despite the internal battery swelling status.

According to embodiments, once antenna tuning is complete, the process 400 continues with subsequent checks and actions similar to the partial implementation flowchart 300, such as evaluating displacement thresholds at S310 and adjusting battery charging voltage at S312, and therefore detailed descriptions of these steps are omitted here.

FIGS. 5-6 illustrate exemplary virtual reality and augmented reality devices that may implement an in-situ battery swell detection and adaptive antenna tuning system, in accordance with one or more embodiments.

As shown in FIG. 5, augmented-reality system 500 may include an eyewear device 502 with a frame 510 configured to hold a left display device 515(A) and a right display device 515(B) in front of a user's eyes. Display devices 515(A) and 515(B) may act together or independently to present an image or series of images to a user. While augmented-reality system 500 includes two displays, embodiments of this disclosure may be implemented in augmented-reality systems with a single NED or more than two NEDs.

In some embodiments, augmented-reality system 500 may include one or more sensors, such as sensor 540. Sensor 540 may generate measurement signals in response to motion of augmented-reality system 500 and may be located on substantially any portion of frame 510. Sensor 540 may represent a position sensor, an inertial measurement unit (IMU), a depth camera assembly, a structured light emitter and/or detector, or any combination thereof. In some embodiments, augmented-reality system 500 may or may not include sensor 540 or may include more than one sensor. In embodiments in which sensor 540 includes an IMU, the IMU may generate calibration data based on measurement signals from sensor 540. Examples of sensor 540 may include, without limitation, accelerometers, gyroscopes, magnetometers, other suitable types of sensors that detect motion, sensors used for error correction of the IMU, or some combination thereof.

Augmented-reality system 500 may also include a microphone array with a plurality of acoustic transducers 520(A)-520(J), referred to collectively as acoustic transducers 520. Acoustic transducers 520 may be transducers that detect air pressure variations induced by sound waves. Each acoustic transducer 520 may be configured to detect sound and convert the detected sound into an electronic format (e.g., an analog or digital format). The microphone array in FIG. 5 may include, for example, ten acoustic transducers: 520(A) and 520(B), which may be designed to be placed inside a corresponding car of the user, acoustic transducers 520(C), 520(D), 520(E), 520(F), 520(G), and 520(H), which may be positioned at various locations on frame 510, and/or acoustic transducers 520(I) and 520(J), which may be positioned on a corresponding neckband 505.

In some embodiments, one or more of acoustic transducers 520(A)-(F) may be used as output transducers (e.g., speakers). For example, acoustic transducers 520(A) and/or 520(B) may be earbuds or any other suitable type of headphone or speaker.

The configuration of acoustic transducers 520 of the microphone array may vary. While augmented-reality system 500 is shown in FIG. 5 as having ten acoustic transducers 520, the number of acoustic transducers 520 may be greater or less than ten. In some embodiments, using higher numbers of acoustic transducers 520 may increase the amount of audio information collected and/or the sensitivity and accuracy of the audio information. In contrast, using a lower number of acoustic transducers 520 may decrease the computing power required by an associated controller 550 to process the collected audio information. In addition, the position of each acoustic transducer 520 of the microphone array may vary. For example, the position of an acoustic transducer 520 may include a defined position on the user, a defined coordinate on frame 510, an orientation associated with each acoustic transducer 520, or some combination thereof.

Acoustic transducers 520(A) and 520(B) may be positioned on different parts of the user's ear, such as behind the pinna, behind the tragus, and/or within the auricle or fossa. Or there may be additional acoustic transducers 520 on or surrounding the car in addition to acoustic transducers 520 inside the car canal. Having an acoustic transducer 520 positioned next to an car canal of a user may enable the microphone array to collect information on how sounds arrive at the car canal. By positioning at least two of acoustic transducers 520 on either side of a user's head (e.g., as binaural microphones), augmented-reality device 500 may simulate binaural hearing and capture a 3D stereo sound field around a user's head. In some embodiments, acoustic transducers 520(A) and 520(B) may be connected to augmented-reality system 500 via a wired connection 530, and in other embodiments acoustic transducers 520(A) and 520(B) may be connected to augmented-reality system 500 via a wireless connection (e.g., a Bluetooth connection). In still other embodiments, acoustic transducers 520(A) and 520(B) may not be used at all in conjunction with augmented-reality system 500.

Acoustic transducers 520 on frame 510 may be positioned along the length of the temples, across the bridge, above or below display devices 515(A) and 515(B), or some combination thereof. Acoustic transducers 520 may be oriented such that the microphone array is able to detect sounds in a wide range of directions surrounding the user wearing the augmented-reality system 500. In some embodiments, an optimization process may be performed during manufacturing of augmented-reality system 500 to determine relative positioning of each acoustic transducer 520 in the microphone array.

In some examples, augmented-reality system 500 may include or be connected to an external device (e.g., a paired device), such as neckband 505. Neckband 505 generally represents any type or form of paired device. Thus, the following discussion of neckband 505 may also apply to various other paired devices, such as charging cases, smart watches, smart phones, wrist bands, other wearable devices, hand-held controllers, tablet computers, laptop computers, other external compute devices, etc.

As shown, neckband 505 may be coupled to eyewear device 502 via one or more connectors. The connectors may be wired or wireless and may include electrical and/or non-electrical (e.g., structural) components. In some cases, eyewear device 502 and neckband 505 may operate independently without any wired or wireless connection between them. While FIG. 5 illustrates the components of eyewear device 502 and neckband 505 in example locations on eyewear device 502 and neckband 505, the components may be located elsewhere and/or distributed differently on eyewear device 502 and/or neckband 505. In some embodiments, the components of eyewear device 502 and neckband 505 may be located on one or more additional peripheral devices paired with eyewear device 502, neckband 505, or some combination thereof.

Pairing external devices, such as neckband 505, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 500 may be provided by a paired device or shared between a paired device and an eyewear device, thus reducing the weight, heat profile, and form factor of the eyewear device overall while still retaining desired functionality. For example, neckband 505 may allow components that would otherwise be included on an eyewear device to be included in neckband 505 since users may tolerate a heavier weight load on their shoulders than they would tolerate on their heads. Neckband 505 may also have a larger surface area over which to diffuse and disperse heat to the ambient environment. Thus, neckband 505 may allow for greater battery and computation capacity than might otherwise have been possible on a stand-alone eyewear device. Since weight carried in neckband 505 may be less invasive to a user than weight carried in eyewear device 502, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 505 may be communicatively coupled with eyewear device 502 and/or to other devices. These other devices may provide certain functions (e.g., tracking, localizing, depth mapping, processing, storage, etc.) to augmented-reality system 500. In the embodiment of FIG. 5, neckband 505 may include two acoustic transducers (e.g., 520(I) and 520(J)) that are part of the microphone array (or potentially form their own microphone subarray). Neckband 505 may also include a controller 525 and a power source 535.

Acoustic transducers 520(I) and 520(J) of neckband 505 may be configured to detect sound and convert the detected sound into an electronic format (analog or digital). In the embodiment of FIG. 5, acoustic transducers 520(I) and 520(J) may be positioned on neckband 505, thereby increasing the distance between the neckband acoustic transducers 520(I) and 520(J) and other acoustic transducers 520 positioned on eyewear device 502. In some cases, increasing the distance between acoustic transducers 520 of the microphone array may improve the accuracy of beamforming performed via the microphone array. For example, if a sound is detected by acoustic transducers 520(C) and 520(D) and the distance between acoustic transducers 520(C) and 520(D) is greater than, e.g., the distance between acoustic transducers 520(D) and 520(E), the determined source location of the detected sound may be more accurate than if the sound had been detected by acoustic transducers 520(D) and 520(E).

Controller 525 of neckband 505 may process information generated by the sensors on neckband 505 and/or augmented-reality system 500. For example, controller 525 may process information from the microphone array that describes sounds detected by the microphone array. For each detected sound, controller 525 may perform a direction-of-arrival (DOA) estimation to estimate a direction from which the detected sound arrived at the microphone array. As the microphone array detects sounds, controller 525 may populate an audio data set with the information. In embodiments in which augmented-reality system 500 includes an inertial measurement unit, controller 525 may compute all inertial and spatial calculations from the IMU located on eyewear device 502. A connector may convey information between augmented-reality system 500 and neckband 505 and between augmented-reality system 500 and controller 525. The information may be in the form of optical data, electrical data, wireless data, or any other transmittable data form. Moving the processing of information generated by augmented-reality system 500 to neckband 505 may reduce weight and heat in eyewear device 502, making it more comfortable to the user.

Power source 535 in neckband 505 may provide power to eyewear device 502 and/or to neckband 505. Power source 535 may include, without limitation, lithium ion batteries, lithium-polymer batteries, primary lithium batteries, alkaline batteries, or any other form of power storage. In some cases, power source 535 may be a wired power source. Including power source 535 on neckband 505 instead of on eyewear device 502 may help better distribute the weight and heat generated by power source 535.

While not shown in FIG. 5, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As shown in FIG. 6, some artificial-reality systems may, instead of blending an artificial reality with actual reality, substantially replace one or more of a user's sensory perceptions of the real world with a virtual experience. One example of this type of system is a head-worn display system, such as virtual-reality system 600 in FIG. 6, that mostly or completely covers a user's field of view. Virtual-reality system 600 may include a front rigid body 602 and a band 604 shaped to fit around a user's head. Virtual-reality system 600 may also include output audio transducers 606(A) and 606(B). Furthermore, while not shown in FIG. 6, front rigid body 602 may include one or more electronic elements, including one or more electronic displays, one or more inertial measurement units (IMUs), one or more tracking emitters or detectors, and/or any other suitable device or system for creating an artificial reality experience.

Artificial-reality systems may include a variety of types of visual feedback mechanisms. For example, display devices in augmented-reality system 500 and/or virtual-reality system 600 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 500 and/or virtual-reality system 600 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 500 and/or virtual-reality system 600 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 6, output audio transducers 606(A) and 606(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

### Hardware Overview

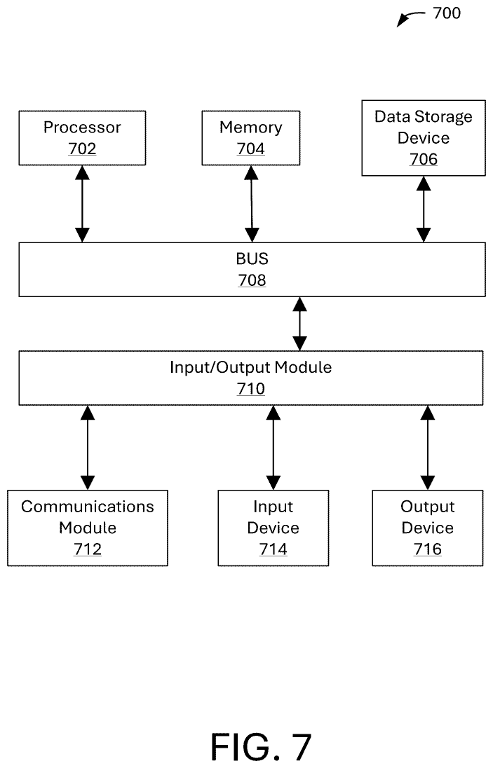

FIG. 7 is a block diagram illustrating an exemplary computer system 700 with which the client and server of FIGS. 1-6, and method(s) described herein can be implemented. In certain aspects, the computer system 700 may be implemented using hardware or a combination of software and hardware, either in a dedicated server, or integrated into another entity, or distributed across multiple entities. Computer system 700 may include a desktop computer, a laptop computer, a tablet, a phablet, a smartphone, a feature phone, a server computer, or otherwise. A server computer may be located remotely in a data center or be stored locally.

Computer system 700 (for example, client 110 and server 130) includes a bus 708 or other communication mechanism for communicating information, and a processor 702 coupled with bus 708 for processing information. By way of example, the computer system 700 may be implemented with one or more processors 702. Processor 702 may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable entity that can perform calculations or other manipulations of information.

Computer system 700 can include, in addition to hardware, code that creates an execution environment for the computer program in question, for example, code that constitutes processor firmware, a protocol stack, a database management system, an operating system, or a combination of one or more of them stored in an included memory 704, such as a Random Access Memory (RAM), a Flash Memory, a Read-Only Memory (ROM), a Programmable Read-Only Memory (PROM), an Erasable PROM (EPROM), registers, a hard disk, a removable disk, a CD-ROM, a DVD, or any other suitable storage device, coupled to bus 708 for storing information and instructions to be executed by processor 702. The processor 702 and the memory 704 can be supplemented by, or incorporated in, special purpose logic circuitry.

The instructions may be stored in the memory 704 and implemented in one or more computer program products, for example, one or more modules of computer program instructions encoded on a computer-readable medium for execution by, or to control the operation of, the computer system 700, and according to any method well-known to those of skill in the art, including, but not limited to, computer languages such as data-oriented languages (for example, SQL, dBase), system languages (for example, C, Objective-C, C++, Assembly), architectural languages (for example, Java, .NET), and application languages (for example, PHP, Ruby, Perl, Python). Instructions may also be implemented in computer languages such as array languages, aspect-oriented languages, assembly languages, authoring languages, command line interface languages, compiled languages, concurrent languages, curly-bracket languages, dataflow languages, data-structured languages, declarative languages, esoteric languages, extension languages, fourth-generation languages, functional languages, interactive mode languages, interpreted languages, iterative languages, list-based languages, little languages, logic-based languages, machine languages, macro languages, metaprogramming languages, multiparadigm languages, numerical analysis, non-English-based languages, object-oriented class-based languages, object-oriented prototype-based languages, off-side rule languages, procedural languages, reflective languages, rule-based languages, scripting languages, stack-based languages, synchronous languages, syntax handling languages, visual languages, wirth languages, and xml-based languages. Memory 704 may also be used for storing temporary variable or other intermediate information during execution of instructions to be executed by processor 702.

A computer program as discussed herein does not necessarily correspond to a file in a file system. A program can be stored in a portion of a file that holds other programs or data (for example, one or more scripts stored in a markup language document), in a single file dedicated to the program in question, or in multiple coordinated files (for example, files that store one or more modules, subprograms, or portions of code). A computer program can be deployed to be executed on one computer or on multiple computers that are located at one site or distributed across multiple sites and interconnected by a communication network. The processes and logic flows described in this specification can be performed by one or more programmable processors executing one or more computer programs to perform functions by operating on input data and generating output.

Computer system 700 further includes a data storage device 706 such as a magnetic disk or optical disk, coupled to bus 708 for storing information and instructions. Computer system 700 may be coupled via input/output module 710 to various devices. Input/output module 710 can be any input/output module. Exemplary input/output modules 710 include data ports such as USB ports. The input/output module 710 is configured to connect to a communications module 712. Exemplary communications modules 712 include networking interface cards, such as Ethernet cards and modems. In certain aspects, input/output module 710 is configured to connect to a plurality of devices, such as an input device 714 and/or an output device 716. Exemplary input devices 714 include a keyboard and a pointing device, for example, a mouse or a trackball, by which a user can provide input to the computer system 700. Other kinds of input devices 714 can be used to provide for interaction with a user as well, such as a tactile input device, visual input device, audio input device, or brain-computer interface device. For example, feedback provided to the user can be any form of sensory feedback, for example, visual feedback, auditory feedback, or tactile feedback; and input from the user can be received in any form, including acoustic, speech, tactile, or brain wave input. Exemplary output devices 716 include display devices, such as an LCD (liquid crystal display) monitor, for displaying information to the user.

According to one aspect of the present disclosure, the client device 110 and server 130 can be implemented using a computer system 700 in response to processor 702 executing one or more sequences of one or more instructions contained in memory 704. Such instructions may be read into memory 704 from another machine-readable medium, such as data storage device 706. Execution of the sequences of instructions contained in main memory 704 causes processor 702 to perform the process steps described herein. One or more processors in a multi-processing arrangement may also be employed to execute the sequences of instructions contained in memory 704. In alternative aspects, hard-wired circuitry may be used in place of or in combination with software instructions to implement various aspects of the present disclosure. Thus, aspects of the present disclosure are not limited to any specific combination of hardware circuitry and software.

Various aspects of the subject matter described in this specification can be implemented in a computing system that includes a back-end component, for example, a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of digital data communication, for example, a communication network. The communication network (for example, network 150) can include, for example, any one or more of a LAN, a WAN, the Internet, and the like. Further, the communication network can include, but is not limited to, for example, any one or more of the following tool topologies, including a bus network, a star network, a ring network, a mesh network, a star-bus network, tree or hierarchical network, or the like. The communications modules can be, for example, modems or Ethernet cards.

Computer system 700 can include clients and servers. A client and server are generally remote from each other and typically interact through a communication network. The relationship of client and server arises by virtue of computer programs running on the respective computers and having a client-server relationship to each other. Computer system 700 can be, for example, and without limitation, a desktop computer, laptop computer, or tablet computer. Computer system 700 can also be embedded in another device, for example, and without limitation, a mobile telephone, a PDA, a mobile audio player, a Global Positioning System (GPS) receiver, a video game console, and/or a television set top box.

The term “machine-readable storage medium” or “computer-readable medium” as used herein refers to any medium or media that participates in providing instructions to processor 702 for execution. Such a medium may take many forms, including, but not limited to, non-volatile media, volatile media, and transmission media. Non-volatile media include, for example, optical or magnetic disks, such as data storage device 706. Volatile media include dynamic memory, such as memory 704. Transmission media include coaxial cables, copper wire, and fiber optics, including the wires forming bus 708. Common forms of machine-readable media include, for example, floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH EPROM, any other memory chip or cartridge, or any other medium from which a computer can read. The machine-readable storage medium can be a machine-readable storage device, a machine-readable storage substrate, a memory device, a composition of matter affecting a machine-readable propagated signal, or a combination of one or more of them.

To illustrate the interchangeability of hardware and software, items such as the various illustrative blocks, modules, components, methods, operations, instructions, and algorithms have been described generally in terms of their functionality. Whether such functionality is implemented as hardware, software, or a combination of hardware and software depends upon the particular application and design constraints imposed on the overall system. Skilled artisans may implement the described functionality in varying ways for each particular application.

As used herein, the phrase “at least one of” preceding a series of items, with the terms “and” or “or” to separate any of the items, modifies the list as a whole, rather than each member of the list (that is, each item). The phrase “at least one of” does not require selection of at least one item; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

To the extent that the term “include,” “have,” or the like is used in the description or the claims, such term is intended to be inclusive in a manner similar to the term “comprise” as “comprise” is interpreted when employed as a transitional word in a claim. The word “exemplary” is used herein to mean “serving as an example, instance, or illustration.” Any embodiment described herein as “exemplary” is not necessarily to be construed as preferred or advantageous over other embodiments.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description. No clause element is to be construed under the provisions of 35 U.S.C. § 72, sixth paragraph, unless the element is expressly recited using the phrase “means for” or, in the case of a method clause, the element is recited using the phrase “step for.”

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

The subject matter of this specification has been described in terms of particular aspects, but other aspects can be implemented and are within the scope of the following claims. For example, while operations are depicted in the drawings in a particular order, this should not be understood as requiring that such operations be performed in the particular order shown or in sequential order, or that all illustrated operations be performed, to achieve desirable results. The actions recited in the claims can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products. Other variations are within the scope of the following claims.

It should be understood that the original applicant herein determines which technologies to use and/or productize based on their usefulness and relevance in a constantly evolving field, and what is best for it and its players and users. Accordingly, it may be the case that the systems and methods described herein have not yet been and/or will not later be used and/or productized by the original applicant. It should also be understood that implementation and use, if any, by the original applicant, of the systems and methods described herein are performed in accordance with its privacy policies. These policies are intended to respect and prioritize player privacy, and to meet or exceed government and legal requirements of respective jurisdictions. To the extent that such an implementation or use of these systems and methods enables or requires processing of user personal information, such processing is performed (i) as outlined in the privacy policies; (ii) pursuant to a valid legal mechanism, including but not limited to providing adequate notice or where required, obtaining the consent of the respective user; and (iii) in accordance with the player or user's privacy settings or preferences. It should also be understood that the original applicant intends that the systems and methods described herein, if implemented or used by other entities, be in compliance with privacy policies and practices that are consistent with its objective to respect players and user privacy.

What is claimed is:

1. A system, comprising:
a battery;
an antenna;
a radio frequency coupler, operably placed in a transmit path of the antenna, that is configured to generate an output signal detailing an amount of power reflected back to a radio frequency power amplifier;
a radio frequency signal conditioning circuitry that is configured to:
receive the output signal from the radio frequency coupler;
convert the output signal for processing by an analog to digital converter; and
a microprocessor that is configured to adjust a charging voltage for the battery based on whether a change in a thickness displacement of the battery, calculated from the output signal, exceeds a swelling response threshold.

2. The system of claim 1, wherein the microprocessor is configured to adjust an antenna tuner, for impedance matching of the antenna, based on the change in the thickness displacement of the battery calculated from the output signal.

3. The system of claim 1, wherein the swelling response threshold comprises a series of progressively increasing thresholds, each associated with a corresponding voltage derating schedule.

4. The system of claim 1, wherein the microprocessor is configured to calculate the thickness displacement using a predefined transfer function correlating reflected power to battery swelling.

5. The system of claim 1, wherein the microprocessor is configured to perform the adjustment of charging voltage iteratively in response to successive threshold violations.

6. The system of claim 1, wherein the microprocessor is configured to poll a timer and sample the transmit antenna power when the timer expires.

7. The system of claim 1, wherein the microprocessor is configured to determine battery swelling based on a relative change in the thickness displacement of the battery from an initial baseline thickness of the battery.

8. The system of claim 1, wherein the microprocessor is configured to continuously monitor antenna impedance to enable early intervention before physical contact or maximum swelling occurs in the battery.

9. A method for managing battery swelling in a device, the method comprising:
sampling transmit antenna power via a radio frequency coupler placed in a transmit path of an antenna;
receiving an output signal from the radio frequency coupler and converting the output signal via signal conditioning circuitry and an analog to digital converter;
calculating a thickness displacement of a battery based on the output signal;
determining whether the thickness displacement exceeds one or more swelling response thresholds; and
adjusting a charging voltage of the battery based on the determination.

10. The method of claim 9, further comprising adjusting an antenna tuner, for impedance matching of the antenna, based on the change in the thickness displacement of the battery calculated from the output signal.

11. The method of claim 9, wherein the thickness displacement is calculated using a predefined transfer function correlating reflected power to battery swelling.

12. The method of claim 9, wherein the charging voltage is adjusted iteratively in response to successive threshold violations.

13. The method of claim 9, wherein the swelling response threshold comprises a series of progressively increasing thresholds, each associated with a corresponding voltage derating schedule.

14. The method of claim 9, further comprising polling a timer, wherein the transmit antenna power is sampled when the timer expires.

15. The method of claim 9, further comprising determining battery swelling based on a relative change in the thickness displacement of the battery from an initial baseline thickness of the battery.

16. The method of claim 9, further comprising continuously monitoring antenna impedance to enable early intervention before physical contact or maximum swelling occurs in the battery.

17. A non-transitory computer-readable storage medium comprising instructions stored thereon, which when executed by one or more processors, cause the one or more processors to perform operations comprising:
sampling transmit antenna power via a radio frequency coupler placed in a transmit path of an antenna;
receiving an output signal from the radio frequency coupler and converting the output signal via signal conditioning circuitry and an analog to digital converter;
calculating a thickness displacement of a battery based on the output signal;
determining whether the thickness displacement exceeds one or more swelling response thresholds; and
adjusting a charging voltage of the battery based on the determination.

18. The non-transitory computer-readable storage medium of claim 17, further comprising instructions stored thereon, which when executed by one or more processors, cause the one or more processors to perform operations comprising adjusting an antenna tuner, for impedance matching of the antenna, based on the change in the thickness displacement of the battery calculated from the output signal.

19. The non-transitory computer-readable storage medium of claim 17, wherein the thickness displacement is calculated using a predefined transfer function correlating reflected power to battery swelling.

20. The non-transitory computer-readable storage medium of claim 17, wherein the charging voltage is adjusted iteratively in response to successive threshold violations.
